(19) United States
(12) Patent Application Publication
(10) Pub. No.: US 2026/0308436 A1
(43) Pub. Date: Oct. 8, 2026

(54) Propylene Carbonate Based Heat Transfer Fluid

(71) Applicant: CCI North America Corporation, Lemont, IL (US)

(72) Inventors: Timo Weide, Lockport, IL (US); Raul Gonzalez, Chicago, IL (US)

(21) Appl. No.: 19/485,126

(22) PCT Filed: Jun. 13, 2024
(86) PCT No.: PCT/US2024/033871

§ 371 Date: Nov. 17, 2025

Related U.S. Application Data
(60) Provisional application No. 63/521,326, filed on Jun. 15, 2023.

(51) Int. Cl. C09K 5/10; H01M 8/04029; H01M 10/653; H05K 7/20

(52) U.S. Cl. CPC C09K 5/10; H01M 8/04029; H01M 10/653; H05K 7/20218

(57) ABSTRACT

A water-free cooling fluid based on alkene carbonates has low toxicity, low electrical conductivity and high heat capacity. The fluid provides corrosion protection for cooled systems and is liquid to −30° C. or lower. Moreover, the fluid shows low viscosity at low temperatures. Some formulations contain dehydrating orthoesters.

### CROSS-REFERENCE TO PRIOR APPLICATIONS

This application is based on and claims the priority and benefit of U.S. Provisional Patent Application 63/521,326 filed on 15 Jun. 2023.

### U.S. GOVERNMENT SUPPORT

N/A

### BACKGROUND OF THE INVENTION

### Area of the Art

The present invention is in the area of heat transfer fluids and more specifically low conductivity liquids with high heat capacity.

### Description of the Background Art

Fuel cells and/or battery systems for mobile use, particularly in motor vehicles, must be operable even at low external temperatures of down to about minus 40° C. A frost-protected coolant circuit is therefore indispensable. Furthermore, temperatures of up to and above 100° C. can be reached during rapid charging of batteries or electric motor operation, and therefore, the heat released by battery charging must be removed to avoid damaging the battery and other components. Therefore, direct battery cooling with dielectric, low electrical conductivity coolants is currently under intense investigation as a more efficient and a safer method than the usage of indirect, water-based cooling (see for example, WO2020264154). A low conductivity, dielectric coolant also allows the direct cooling of the electric motors and associated motor electronics.

The use of conventional water-based antifreezes, employed in internal combustion engines and based on monoalkylene glycols, and in particular, monoethylene glycol, optionally in conjunction with other glycols, could not be used in fuel cell, battery or electronic systems as a direct coolant unless there is complete electrical insulation of the coolant channels. Water-based heat transfer fluids have high electrical conductivity because of the salts and ionizable compounds present therein as corrosion inhibitors. High electrical conductivity adversely affects the function of the fuel cell or battery system by effectively creating a short circuit. Furthermore, in the event of an accident which causes battery leakage there is a risk of short circuit due to shorting of anode and cathode by the water-based heat transfer fluid and/or evolution of hydrogen gas by electrolysis which carries additional risk potential. The risk of a short circuit and hydrogen evolution can be minimized by using low conductivity water-based coolants (for examples see DE10063951A1, U.S. Pat. No. 7,419,617B2, and US Published Patent Application 2013/0092870A2); nevertheless, any damage to the battery cell entails a risk of a water-based coolant and electrolyte coming into contact and forming dangerous hydrogen fluoride and other reaction products through reaction of the protic coolant with the often-employed battery electrolyte lithium hexafluorophosphate (LiPF₆). This risk is further increased by the presence of water, for example because of the hygroscopic nature of the coolant.

Not only is removal of heat required for fuel cell, battery and electronic systems for automotive applications, heat-removal is also a common issue in modern server farms to prevent overheating of electronic devices. As computational power increases with datacenters and telecommunication systems, so does the heat output. Although the desire for increasing processing or storage density in these datacenters is large, the thermal challenges remain a significant obstacle. Consequently, there exists a need for efficient, low power devices for cooling of server systems, thereby facilitating increased processing and storage densities of the server systems. The use of liquid cooling is becoming increasingly popular for such devices and is replacing air cooling in many of the heat transfer processes to increase energy efficiency. Usually, fluorinated organic liquids are used in such heat transfer systems because water or water-based systems exhibit significant electrical conductivity which may cause an electrical short circuit on direct contact with electrical components, or, in the case of indirect cooling, in case of a leakage of the coolant loop. Although fluorinated organic liquids are usually non-flammable, they are environmentally questionable due to their ozone-depleting and global warming potential and are, therefore, not ideal.

It is also necessary for heat-transfer fluids to maintain their usually initially low electrical conductivity and dielectric properties over a long period of time and not exhibit increases in conductivity due to various decomposition processes, often the formation ions by oxidation or corrosion, or water absorption over time.

Monoethylene glycol (EG) boils at 197° C. under standard pressure and monoethylene glycol-containing compositions therefore have a significant vapor pressure at temperatures above about 170° C., thus limiting their use as heat-transfer liquids at high temperatures. The same applies to monopropylene glycol (PG) which has a boiling point at standard pressure of 188° C. Furthermore, PG compositions are either solid at low temperatures (−30° C.) or have a very high viscosity, both of which limits their use as waterless heat transfer fluids although both glycols are used in standard coolants for internal combustion engines when diluted with water. Propylene carbonate as an alternative fluid for water-based (U.S. Pat. No. 3,607,756) and waterless heat transfer applications (DE 102007016738 A1, U.S. Pat. No. 11,108,102 B2) has been reported.

Recently, driving factors like product safety, environmental impact, and the extent to which components are natural have been a focus of scientific study and product development. In fact, the effort towards environmental impact awareness is a universal concern, recognized by many government agencies. Carbon dioxide emissions are singled out as the largest component of the collection of greenhouse gases into the atmosphere, and therefore, responsible for global warming. While biodegradability is an important factor in protecting the environment, biodegradation of glycols derived from fossil-based sources has the unavoidable consequence of releasing previously fixed carbon dioxide into the atmosphere. Biobased, e.g., fermentatively derived, materials are organic materials in which the carbon source comes from recently fixed carbon dioxide present in the atmosphere using sunlight energy. Renewable glycols, wherein the carbon center is from a new carbon source, are available affording a net zero carbon dioxide release to the atmosphere when biodegraded (US Published Patent Application No. 2007/0200088 A1).

If heat is to be transferred at a relatively high temperature, the cooling system must either be configured for higher pressures or recourse must be made to oils, for example mineral oils, silicone oils, synthetic oils or fatty acid esters, or fluorinated hydrocarbons as heat transfer fluids. The former is technically complex and cooling systems are, therefore, typically open to the atmosphere. The latter cooling approach has the disadvantages that these compounds exhibit a low heat capacity and upon contamination with water due to the open nature of the cooling system, separate into two phases due to their low miscibility with water. It is, therefore, an object of the present invention to provide a non-aqueous heat transfer fluid which may be used with electronic components.

The strategy of using organic molecules as dehydrating agents remains a relatively neglected approach. However, organic molecules with well characterized dehydrating properties—such as ortho esters, acetals, hemiacetals, ketals, and hemiketals—present themselves as excellent starting points for the development and optimization of novel functional fluid dehydrating reagents. Orthoesters are highly reactive owing to the electron-deficient central carbon atom. The reaction of an orthoester with water is irreversible, and water is removed or quasi trapped in a carboxylic ester. Orthoesters react very specifically with water. Under absence of water orthoesters are a stable base stock component. Orthoesters are hydrolyzed catalytically by Bronsted acid, ammonium salts of strong Bronsted acids, or Lewis acids.

### SUMMARY OF THE INVENTION

The major requirements for a heat transfer fluid are following:
Nontoxic or at most minimal toxicity,
Environmentally friendly,
Temperature resistant up to 200° C.,
Non-flammable or at least a very high flash point,
Liquid down to −30° C. or lower,
A low viscosity at low temperature to allow pumpability,
Corrosion resistant, and
Inexpensive.

Currently the most frequently used heat transfer systems are based on aqueous solutions of ethylene glycol or propylene glycol. Where toxicity is an issue, propylene glycol is preferred. The disadvantages of the currently used water-glycol based fluids are:
Their high-water content causes a high pressure above a temperature of 100° C., and at temperatures above 200° C. special requirements for material and proper technical measures need to be taken since the pressure can reach 2-4 bar,
Water-glycol based heat transfer fluids decompose at higher temperatures,
Glycol decomposition results in increases of conductivity and corrosion, and
Water-glycol based heat transfer fluids dissolve ionic species resulting in an increase of electrical conductivity and possible corrosion behavior.

In the prior art these problems have been addressed by using non-water-based fluids such as those based on mineral oil. Such non-water-based heat transfer fluids can be heated to over 240° C., nevertheless, they often have high viscosities at low temperatures or are, in addition, when mineral oil based, water pollutants and/or have a high melting points. Mineral oil-based heat transfer fluids are also not very desirable because they can be difficult to completely remove due to their non-water miscible properties.

The object of the present invention accordingly is to provide new non-water-based heat transfer fluids which are useful in fuel cells, and for direct cooling of battery systems, electric motors, and electric systems in general. These fluids are employable at relatively high temperatures and exhibit a high heat capacity but are also suitable for use in open cooling systems and exhibit compatibility with water. The ideal coolant should further exhibit low conductivity dielectric properties and retain these properties in use. The inventors have identified four groups of compounds, namely Component A1, Component A2, Component A3, and Component A4 that are useful in the present invention. Component A1 compounds are alkene carbonates and are required for the inventive compositions. Component A2 compounds enhance the effectiveness of the A1 Components and are combined with A1 compounds in many preferred embodiments. The A3 Component compounds enhance certain compositions and optionally may be included in the formula either with or without A2 Component compounds. The A4 Component compounds are dehydrating orthoesters and may be included in the formula either with or without A2 Component and A3 Component compounds. A4 component compounds are preferably included in the formula when maintenance of dry (e.g. water-free) conditions are required.

A1 The required A1 Component is at least one alkylene carbonate derivative of formula (I):

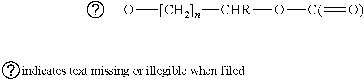

wherein R is hydrogen or a C1- to C4-alkyl, preferable hydrogen or methyl, most preferable methyl, and n is 1 to 3, most preferably 1.

A2 The heat transfer fluid may also contain an A2 compound that is a derivative of formula (II):

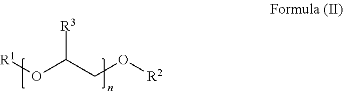

wherein R¹ is hydrogen or a C1- to C4-alkyl, preferably hydrogen, methyl, or ethyl, more preferably hydrogen or methyl and most preferably hydrogen, R² is a C1- to C6-alkyl, preferably methyl, ethyl, or n-butyl, more preferably methyl or n-butyl and most preferably methyl or n-butyl. R² may also be an aryl group, most preferably phenyl. R³ is hydrogen or methyl, and n is on arithmetic average of a number from 3.0 to 4.0, representing the range of values resulting from the ethoxylation reaction. When R² is an aryl-group, n is on arithmetic average a number from 1-2, particularly preferably 1.

It is preferable that the A2 Component be a substantially pure compound of formula (II) where n=3 or a mixture of compounds of formula (II) where n=3 and n=4. For the compounds of formula (II) in the mixture, n is on arithmetic average preferably from 3.0 to 3.6, particularly preferably from 3.0 to 3.5, very particularly preferably from 3.05 to 3.4, and more preferably from 3.1 to 3.3 and most preferably from 3.15 to 3.2.

The purity of compounds of formula (II) where n=3 is generally at least 80 wt %, preferably at least 85 wt %, more preferably at least 90 wt %, with at least 95 wt % and especially 97.5 wt % the most highly preferred. The remainder is predominantly made up of compounds of formula (II) where n=2 and n=4. By contrast, in the case of compounds of formula (II) where n=4 the purity is only at least above 50 wt %, preferably at least 55 and more preferably at least 60 wt %. The remainder is preferably made up of compounds of formula (II) where n=3 and, to a lesser extent, n=5.

Preferred A2 Components comprising substantially pure compounds are:
Triethylene glycol monomethyl ether,
Tripropylene glycol monomethyl ether, and
Triethylene glycol monoethyl ether.

Preferred A2 Components comprising mixtures of compounds of formula (II) where n=3 and n=4 are:
Triethylene glycol monomethyl ether in admixture with tetraethylene glycol monomethyl ether,
Triethylene glycol monoethyl ether in admixture with tetraethylene glycol monoethyl ether; and
Tripropylene glycol monomethyl ether in admixture with tetrapropylene glycol monomethyl ether.

Also usable, albeit generally less preferred, are mixtures of compounds of formula (II) where n=3 and n=4 having different radicals R². Such mixtures are:
Triethylene glycol monomethyl ether in admixture with tetraethylene glycol monoethyl ether,
Triethylene glycol monoethyl ether in admixture with tetraethylene glycol monomethyl ether.

Also usable, albeit less preferred, are mixed alkylene glycol derivatives of formula (II) where for each n R³ may independently of one another be the same or different, e.g., tri- and tetraalkylene glycol derivatives of formula (II) or mixtures of ethylene oxide and propylene oxide. In the case of mixtures of compounds of formula (II) where n=3 and n=4 the weight ratio is preferably 100:0 to 40:60, more preferably 95:5 to 50:50, most preferably 90:10 to 60:40, wherein from 85:15 to 70:30 is more preferred and 85:15 to 75:25 is most preferred. Also usable are derivatives of formula (II) such as phenoxyethanol and phenoxypropanol with R² being phenyl and R³ being hydrogen or -methyl respectively with n=1.

US Published Patent Application No. 2021/0403782 discloses a coolant for fuel cells comprising an A2 Component, wherein the composition comprises up to 50 wt % of deionized water based on the total aqueous mixture, and which shows an electrical conductivity at 25° C. of not more than 50 μS/cm. It is conversely true that higher homologs of the A2 component with n>5, and higher molecular-weight homologs of an A2 component result in a high viscosity of the composition and thus impede the pumpability of the composition. A high viscosity entails elevated pump power usage and thus elevated energy consumption by the pumps. The higher homologues, especially of A2 Components with n>5, additionally have elevated melting points, and therefore, there is a risk they may precipitate at low temperatures. It is conversely true that lower homologs of the A2 Component with n=1 and 2 result in an undesirable lowering of the boiling point and also result in excessive reduction of the viscosity of the composition. Excessively low viscosity may be undesired in certain applications since low-viscosity liquids easily penetrate seals thereby causing leaks. Leaks can also be caused by excessive swelling or shrinking of rubber and polymeric materials. Polymer swelling is adjusted by selectively choosing A2 compounds of desired polarity. Polarity is decreased by R¹=C1-C4 instead of hydrogen, R²=C2-C6 instead of methyl, and R³=methyl instead of hydrogen. High polarity A2 compounds are represented by R¹=hydrogen and R²=methyl or hydrogen.

A3 The A3 Components consists of alkylene glycols, polyalkylene oxides, polyhydric alcohols, glycerin, or a mixture of two or more of these compounds. More preferably, the A3 Component is selected from the group consisting of monoethylene glycol, monopropylene glycol (1,2-propanediol), 1,3-propanediol, 1,4-butanediol, glycerol and mixtures thereof. 1,3 propanediol and 1,4-butanediol are environmentally friendly and have high boiling points. 1,3-propanediol and 1,4-butanediol can also be produced via a biological route using genetically modified organisms. A3 Components can be chosen to adjust the polarity, and therefore, to fine-tune rubber and elastomer compatibility when needed.

A4 The A4 Component consists of an orthoester derivative of formula (IV) or formula (IVb):

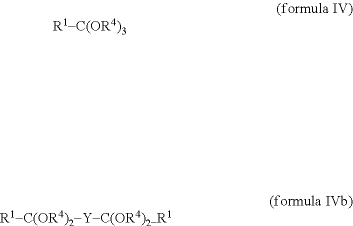

wherein R¹ is hydrogen or a C1- to C6-alkyl, preferably hydrogen, methyl, or ethyl, particularly preferably hydrogen or methyl and very particularly preferably methyl, and R⁴ is an organic radical of the following structure:

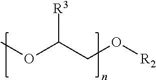

wherein
R² is C1- to C6-alkyl, preferably methyl, ethyl, or n-butyl, particularly preferably methyl, and R³ is hydrogen or methyl, preferably hydrogen,
n is a number from 0 to 3, and
Y is —CH₂—CH₂—O—CH₂—CH₂—, or —CH₂—CH₂—S—CH₂—CH₂—, or a cyclic orthoester of formula (V) and (Vb)

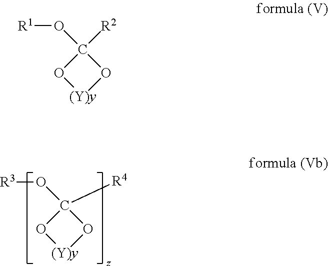

where:
R¹ and R³ are independently selectable and are selected from a C1 to C6 substituted or non-substituted, branched or straight chain, alkyl or alkyl ether group;
R² and R⁴ are independently selectable and are selected from a C1 to C6 substituted or non-substituted, straight or branched chain, alkyl group;
Y is independently selectable and is a substituted or non-substituted alkyl group;
y is an integer of 1 to 3;
z is an integer of 2 to 6.

Bis(2-hydroxyethyl)sulfide and 2,2-thiodipropionic acid derivatives, often in their ester forms, are industrially used synergistically as secondary antioxidants together with phenolic and aminic antioxidants. When Y is —CH₂—CH₂—S—CH₂—CH₂— in formula (IVb) an orthoester dehydrating property can be combined with antioxidant properties. This is especially advantageous as moisture and oxygen together can expose a functional fluid to severe corrosive conditions.

R¹ and R³ may be selected from CH₃—, CH₃CH₂—, CH₃O(CH₂)n-, where n is an integer of 1 to 5. R³ can also be —CH₂CH₂-group and function as a linker. R² and R⁴ may be independently selected from —CH₃, —CH₂CH₃, CH₂CH₂CH₃, —CH₂CH(CH₃)₂, and —CH₂C(CH₃)₃. Y is a linker between the two oxygen atoms. It may be independently selectable and may, for example, be —CH— or —CH(CH₃)—. y may be an integer of 1 to 3. Hence the two oxygen atoms may be linked, for example, by —CH₂—, —CH₂CH₂— or —CH₂CH₂CH₂—, y is typically 2. z may be an integer of 2 to 6, typically 2 or 3.

Base stocks for Components A1, A2, A3, and A4 can be mixed in any ratio.

Additional Additives. Those of skill in the art will recognize that a successful cooling fluid may require additional well-known additives. The suitability and compatibility of any particular additive with any particular mixture of Components A1, A2, A3 and/or A4 should be ascertained. The composition according to the invention may also optionally contain one or more additives selected from the group consisting of
Antioxidants,
Corrosion inhibitors,
Anti-wear additives,
Extreme pressure additives,
Friction modifiers,
Surfactants,
Dispersants,
Defoamers,
Buffering agents,
Dyes; and
Emulsifiers.

Such additives are in each case optional, and the additives may each, independently of one another, be present in the compositions according to the invention in amounts of 0 to 5.0 wt %, preferably from 0.001 to 3.5 wt %, and more preferably from 0.002 to 2.5 wt %. To achieve the low electrical conductivity required according to the invention it is preferable to eliminate compounds in salt (ionic) form and readily dissociating compounds, particularly acids, when selecting the employed components. A preferred embodiment therefore comprises employing the further additives described above in a form which is substantially non-ionic under the usage conditions.

### DETAILED DESCRIPTION OF THE INVENTION

The following description is provided to enable any person skilled in the art to make and use the invention and sets forth the best modes contemplated by the inventor of carrying out his invention. Various modifications, however, will remain readily apparent to those skilled in the art, since the general principles of the present invention have been defined herein specifically to provide low conductivity heat transfer fluids with high heat capacities.

Propylene carbonate (4-methyl-1,3-dioxolan-2-one), has the following advantageous properties which render it very suitable as heat transfer fluid for fuel cells and for direct cooling (immersion cooling) of battery and electric systems and electric motors:
Non-toxic,
Environmentally friendly and biodegradable,
Melting point of −48° C.,
Boiling point of about 242° C.,
High flash point of 132° C.,
High auto-ignition temperature of 455° C.,
Low viscosity even at low temperatures,
Low conductivity of less than 1 μS/cm,
Non-corrosive,
No decomposition, even at high temperatures,
Miscible with water (240 g/L at 20° C.),
Non-hydroscopic,
Not rated as VOC (volatile organic compound); and
Readily available and inexpensive.

However, in the presence of an acid, base, metal oxide or salt, propylene carbonate may decompose liberating CO₂. In an aqueous solution, the decomposition products are propylene glycol and CO₂.

Propylene carbonate is a reagent with extremely versatile uses. It has the properties of a polar, aprotic solvent with a high molecular dipole moment. Propylene carbonate is mainly used as a solvent for multiple applications and systems, e.g., for resins, for paints and paint strippers, for polymers like polyacrylate and nylon, as a solvent for extractions, as a solvent in pharmaceuticals, and for gas absorption, as well as many other applications. Due to propylene carbonates high dielectric constant, it is used as an electrolyte in lithium batteries creating an effective solvation shell around lithium or other alkali metal ions.

Test results showed that propylene carbonate (PC) does not induce any significant toxic effects at concentrations of up to 5000 mg/kg/day or any developmental toxicity and was therefore found to be practically nontoxic. Emissions from propylene carbonate do not pose a hazard to workers or residents and PC shows a very low aquatic toxicity and environmental impact because of its rapid biodegradability (80% in 10 days). Propylene carbonate is not classified in a DOT hazard class and has a National Fire Protection Association (NFPA) health rating of 1, a flammability rating of 1, and a reactivity rating of 0—stable even under fire exposure conditions and does not react with water (EPA/600/R-98/068: Environmental Profile for Propylene Carbonate).

Both ethylene and propylene carbonate are prepared by carbonation of epoxides, ethylene or propylene oxide respectively:

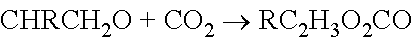

This synthesis of alkylene carbonate is particularly attractive since the production of these epoxides consumes carbon dioxide and shows a very attractive CO₂ balance rendering propylene carbonate a good example of a green process (Demirel, Yasar. J. Chem. Eng. Process Technol, vol. 6, no. 3, 2015). Propylene carbonate can also be produced from urea and propylene glycol. This synthesis route allows recycled propylene to be used as a feedstock and extends the green production process. When propylene carbonate is made from renewable-based propylene oxide, PC can possibly be carbon dioxide negative.

The compositions according to the invention are subject to the following provisions:
They comprise less than 0.5 wt % of water, preferably less than 0.3, more preferably less than 0.25, most preferably less than 0.20, with less than 0.15 and especially less than 0.1 wt % being the most highly preferred.
The low water content according to the invention in conjunction with the A1 and A2 components affords an elevated boiling point according to the invention because a higher water content limits the boiling point of a composition with A1 Components to about 150° C. or lower. The presence of even small amounts of water drastically lowers the boiling point and increases the conductivity of the compositions.

The compositions according to the invention preferably have a specific heat capacity at 50° C. of at least 1.8 kJ/kg*K, more preferably of at least 1.9, much more preferably at least 2.0 and most preferably of at least 2.1 kJ/kg*K. The compositions according to the invention preferably have a thermal conductivity of at least 0.15 W/m*K. The specific heat capacity of the propylene carbonate-based heat transfer fluid can be increased by addition of organic solvents. It was surprisingly found that the heat capacity of the propylene carbonate-based heat transfer fluid can be increased by the addition of glycol ethers compared to neat propylene carbonate. Formulation K and M (Table Ill, below) provide a higher heat capacity greater than regular water-based heat transfer fluids. Triethylene glycol monomethyl ether (MTG), triethylene glycol mono-n-butyl ether (BTG), tripropylene glycol monomethyl ether, phenoxypropanol, and phenoxyethanol were selected as examples.

The compositions according to the invention preferably have a boiling point at 1013.25 hPa (standard atmospheric pressure) of at least 200° C., preferably at least 210° C., more preferably of at least 220° C., and most preferably at least 230° C. This ensures that the compositions remain liquid even at high ambient temperatures and can function as heat-transfer fluids without the vapor pressure above the compositions increasing excessively. The compositions according to the invention may therefore be employed in open systems even at high temperatures. When orthoesters are used as dehydrating reagents, oligomeric orthoesters of formula (Ib) and formula (IIb) are preferred due to their higher boiling points. An orthoester, RC(OR′)₃, is a functional group containing three alkoxy groups attached to a carbon atom. Their structural similarity and polarity render orthoesters ideal candidates to be used in propylene carbonate based functional fluids.

TABLE I
Physical parameters for Exemplary Propylene Carbonate/Glycol mixtures.

| Component | wt % | | | | | | | | | |
|---|---|---|---|---|---|---|---|---|---|---|
| Formulation | A | B | C | D | E | F | G | H | I | J |
| Propylene | 100 | 95 | 60 | 60 | 30 | 60 | 40 | 60 | 40 | 60 |
| Carbonate | | | | | | | | | | |
| Propylene | 0 | 0 | 40 | 30 | 60 | 0 | 0 | 0 | 0 | 10 |
| Glycol | | | | | | | | | | |
| MTG/BTG | 0 | 0 | 0 | 10 | 10 | 40 | 60 | —/40 | —/60 | 30 |
| DI-Water | 0 | 5 | 0 | 0 | 0 | 0 | 0 | 0 | 0 | 0 |
| Viscosity at | 2.2 | 1.9 | 5.3 | 4.3 | 11.4 | 3.4 | 4.2 | 4.1 | 5.7 | 2.7 |
| 25° C. | | | | | | | | | | |
| [mm²/s] | | | | | | | | | | |
| Viscosity | 17.1 | FREEZES | 75.7 | 148.0 | 4034.5 | 67.3 | 115.6 | 80.2 | 174.3 | 89.2 |
| at −40° C. | | | | | | | | | | |
| [mm²/s] | | | | | | | | | | |
| Boiling | 242.6 | 123.5 | 197.9 | 204.7 | 193.3 | 237.1 | 240.2 | 246.4 | 250.7 | 220.4 |
| Point [° C.] | | | | | | | | | | |
| Freeze | <−40 | >−40 | <−40 | <−40 | <−40 | <−40 | <−40 | <−40 | <−40 | <−40 |
| point [° C.] | | | | | | | | | | |

TABLE II
More physical parameters for Exemplary Propylene Carbonate/Glycol mixtures.

| Component | wt % | | | | | |
|---|---|---|---|---|---|---|
| Formulation | K | L | M | N | O | P |
| Propylene carbonate | 60 | 40 | 60 | 40 | 60 | 40 |
| Tripropylenglycol- | 40/0/0 | 60/0/0 | 0/40/0 | 0/60/0 | 0/0/40 | 0/0/60 |
| methylether/Phenoxy- | | | | | | |
| propanol/Phenoxy- | | | | | | |
| ethanol | | | | | | |
| DI-Water | 0 | 0 | 0 | 0 | 0 | 0 |
| Viscosity at 25° C. | 3.4 | 4.4 | 4.3 | 7.0 | 4.0 | 6.4 |
| [mm²/s] | | | | | | |
| Viscosity at −40° C. | 58.7 | 114.9 | 232 | 2418 | 184 | FREEZES |
| [mm²/s] | | | | | | |
| Boiling Point [° C.] | 238.1 | 234.2 | 238.2 | 239.2 | 241.9 | 241.3 |
| Freeze point [° C.] | <−40° C. | <−40° C. | <−40° C. | <−40 | <−40° C. | >−40 |

TABLE III
Thermal Conductivity and Specific Heat Capacity of two selected fluids

| | Thermal Conductivity | Specific Heat Capacity |
|---|---|---|
| Formulation | [W/(m*K)] | [J/(g*K)] |
| K | 0.159 | 5.48 |
| M | 0.161 | 4.43 |
| PC (100%) | 0.21 | 2.6 |
| H₂O | 0.6 | 4.2 |
| Monoethylene | 0.43 | 3.3 |
| Glycol/H₂O (50 v %) | | |

The compositions according to the invention have an advantageous viscosity which is neither too low nor too high. They preferably have a kinematic viscosity at 100° C. according to ASTM D445 of at most 4 mm²/s, preferably of at most 3 and most preferably of at most 2 mm²/s. Moreover, they preferably have a kinematic viscosity at minus 40° C. according to ASTM D445 of not more than 600 mm²/s, preferably of not more than 500, more preferably of not more than 400 and most preferably of not more than 350 mm²/s. It is an advantage of the compositions according to the invention that over a wide temperature range, preferably from minus 40° C. to plus 100° C., they exhibit not only a lower viscosity but also a smaller change in viscosity than conventional coolants based on water and monoethylene glycol. Accordingly, for the compositions according to this disclosure the change in kinematic viscosity in the temperature range from minus 40° C. to plus 100° C. is not more than about 500 mm²/s, and thus varies to a lesser extent than a mixture of water and monoethylene glycol. As a result, the cooling system may employ pumps having a lower conveying power output, so that less energy is required for conveying the coolant in the cooling system. All formulations show a low conductivity of less than 2 μS/cm.

For sensitive applications water absorption can be critical and lead to failure. Formulation K and M were evaluated under Wet Equilibrium Reflux Boling Point (Wet ERBP) according to FMVSS 116 section S6.2 (CFR Title 49, chapter V, part 571, standard No. 116) and the moisture uptake of both formulations K and M was compared to triethylene glycol monomethyl ether (MTG). The results below show that propylene carbonate formulations with different glycol ethers absorb less moisture than standard polar glycol ethers. Formulations K and M were both single phase mixtures after the moisture absorption test. Orthoesters can react almost quantitatively with trace quantities (<0.2%) of water at room temperature, and no more than stoichiometric amounts of ortho ester is required for complete water removal. Due to these properties, orthoesters are suitable for removing water. Oligomeric orthoesters of formula (Ib) and formula (IIb) have the ability to scavenge more water by weight than monomeric orthoesters with a high molecular weight (improved atom economy) and are preferred. In certain cases, a Lewis or Bronsted acid catalyst is needed. The catalyst can also be provided on solid support, e.g. strong acidic ion exchange resin (SAC).

TABLE IV
Moisture absorption over 2 days according to FMVSS 116, section S6.2.

| | Start [%] | Finish [%]; 2 days |
|---|---|---|
| MTG (reference) | 0.5 | 8.8 |
| Formulation K | 0.13 | 3.5 |
| Formulation M | 0.025 | 0.92 |

TABLE V
Moisture Scavenging properties of orthoesters.

| | | | | |
|---|---|---|---|---|
| Base | Propylene Carbonate | 95 | | 95 |
| Fluid | 2-Methoxyethanol (Reference) | | 95 | |
| | Formula (II): R² = —CH3, R¹ = -Ethyl, Y = | 5 | 5 | |
| | —CH2CH2— | | | |
| | Formula (I): R1 = —CH3, 2- | | | 10* |
| | Methoxyethanol | | | |
| Water | Water | 0.5 | 0.5 | 0.5 |
| Catalyst | p-Toluenesulfonic acid | 0.01 | 0.01 | 0.01 |
| Results | Water-before (%) | 0.5 | 0.5 | 0.5 |
| | Water-after (%) | 0.007 | 0.006 | 0.002 |

*This specific Orthoester has a high molecular weight; higher amount is needed to react stoichiometrically.

Composition K was prepared and evaluated under the conditions (modified as explained below) set forth by ASTM D1384. ASTM D1384 is a standard test method for general corrosion of a variety of metals typically found in the cooling system and/or heating system of internal combustion engines. ASTM D1384 was modified to evaluate the metals that will be used in a fuel cell assembly. Such metals include stainless steel, aluminum alloys and copper. ASTM D1384 was further modified so that the test formulation K was not diluted with “corrosive water”.

According to ASTM D1384 the metal specimens were immersed for 336 hours in the heat transfer composition and maintained at a temperature of 88° C. under an aeration rate of 100 mL/min. Afterwards the weight change of the metal specimens was measured. A weight loss of 10 mg for stainless steel, and 30 mg for each of aluminum and copper is the maximum allowed to pass ASTM D1384.

The heat transfer compositions of the present invention provide general corrosion inhibition for aluminum, stainless steel, and copper. For example, formulation K exhibited a stainless-steel loss of 0.2 mg/coupon, and an aluminum and copper loss of 0.3 and 2.4 mg/coupon respectively. The physical parameters of the fluid after the test did not change. The water content after the modified ASTM corrosion test was measured as 650 ppm.

After completion of the modified ASTM D1384 test, electrical resistance was measured for formulation K. The compositions of the present invention provide high electrical resistance even after exposure to different metal surfaces over extended test times. The electrical conductivity after the test was less than 2 μS/cm. Waterless heat transfer fluids, compared to standard glycol/water-based heat transfer fluids, using the components disclosed herein have a much lower tendency to dissolve ionic species and inorganic salts, and therefore, will remain low in conductivity even when the heat transfer system is contaminated, e.g., with flux from radiator manufacturing, or exposed to high temperature of a period of time. Formulations K and L were evaluated for heat resistance and ion elution at ambient and elevated temperature. An aqueous mono ethylene glycol solution was used as a reference. Conditions for heat resistance are as follows: 100 mL solution was stored at 110° C. for 3.5 days and the electrical conductivity measured after test completion. The ion elution test is performed with a 0.1% flux solution at 25° and 120° C., respectively. Solution are stirred at constant temperature for 2 hours. As pH is defined only in aqueous solutions pH values are not reported for non-aqueous solutions.

TABLE VI
Conductivity of Preferred compositions:

| | | | MEG |
|---|---|---|---|
| | K | L | (Reference) |
| Propylene Carbonate | 60.00 | 60.00 | |
| Tripropylene Glycol Monomethyl | 40.00 | | |
| Ether | | | |
| 1-Phenoxy-2-Propanol | | 40.00 | |
| Monoethylene Glycol | | | 50 |
| DIW | | | 50 |
| Conductivity μS/cm, before | 1.819 | 1.003 | 0.468 |
| Conductivity μS/cm, after Heat | 0.485 | 0.931 | 4.606 |
| Resistance | | | |
| Conductivity μS/cm, after Ion Elution | 2.278 | 1.247 | 88.49 |
| pH, before High Temp Ion Elution | — | — | 6.65 |
| pH, after High Temp Ion Elution | — | — | 7.04 |
| Conductivity μS/cm, before High | 0.470 | 0.908 | 1.072 |
| Temperature Ion Elution | | | |
| Conductivity μS/cm, after High | 4.246 | 2.196 | 173.1 |
| Temperature Ion Elution | | | |

The following claims are thus to be understood to include what is specifically illustrated and described above, what can be obviously substituted and also what incorporates the essential idea of the invention. Those skilled in the art will appreciate that various adaptations and modifications of the just-described preferred embodiment can be configured without departing from the scope of the invention. The illustrated embodiment has been set forth only for the purposes of example and that should not be taken as limiting the invention. Therefore, it is to be understood that, within the scope of the appended claims, the invention may be practiced other than as specifically described herein.

What is claimed is:

1. A ready-to-use heat transfer fluid for direct cooling of electric systems comprising:
an A1 Component and at least one of an A2 and an A3 component,
wherein the A1 Component is one or more alkylene carbonate derivatives of formula, 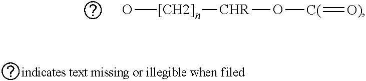
wherein R is hydrogen or a C1- to C4-alkyl, and n is 1 to 3,
wherein the A2 Component is one or more alkylene glycol ether derivatives of formula (II), 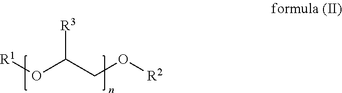
wherein R¹ is hydrogen or a C1- to C6-alkyl, R² is a C1- to C6-alkyl, or aryl, R³ is hydrogen or methyl, and n is a number from 3.0 to 4.0, and wherein a derivative of formula can also be phenoxyethanol and/or phenoxypropanol, and
wherein the A3 Component is selected from the group consisting of monoethylene glycol, monopropylene glycol, 1,3-propandiol, 1,4-butandiol, glycerol and mixtures thereof.

2. The ready-to-use heat transfer fluid of claim 1 further comprising: an A4 Component which is an orthoester derivative of formula (IV) or formula (IVb), 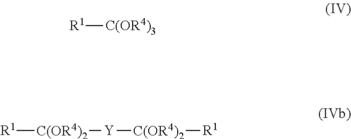
wherein
R¹ is hydrogen or a C1- to C6-alkyl, and R⁴ is the following organic radical, 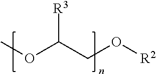
R² is a C1- to C6-alkyl, R³ is hydrogen or methyl, Y is —CH₂—CH₂—O—CH₂—CH₂—, or —CH₂—CH₂—S—CH₂—CH₂—, and
n is a number from 0 to 3, or a cyclic orthoester of formula (II) and (IIb) 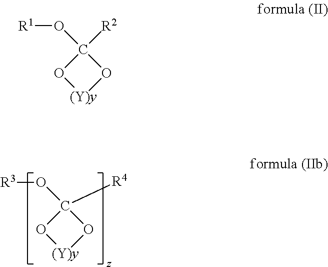
where:
R¹ and R³ are independently selectable and are selected from a C1 to C6 substituted or non-substituted, branched or straight chain, alkyl or alkyl ether group, R² and R⁴ are independently selectable and are selected from a C1 to C6 substituted or non-substituted, straight or branched chain, alkyl group, Y is independently selectable and is a substituted or non-substituted alkyl group, y is an integer of 1 to 3, and z is an integer of 2 to 6.

3. The ready-to-use heat transfer fluid of claim 1, wherein the moisture absorption properties are controlled by addition of nonpolar alkylene glycol ethers which are derivatives according to the formula for A2 Component.

4. The ready-to-use heat transfer fluid of claim 1, further comprising one or more additives selected from the group consisting of antioxidants, corrosion inhibitors, anti-wear additives, extreme pressure additives, friction modifiers, surfactants, dispersants, defoamers, buffering agents, and dyes.

5. The ready-to-use heat transfer fluid of claim 1, wherein the composition has an electrical conductivity at 25° C. of not greater than 5 uS/cm.

6. The ready-to-use heat transfer fluid of claim 1, wherein the composition has a boiling point at 1013 hPa of at least 200° C.

7. The ready-to-use heat transfer fluid of claim 1, wherein the composition has a kinematic viscosity at 100° C. according to ASTM D445 of not greater than 4 mm²/s.

8. The ready-to-use heat transfer fluid of claim 1, wherein the composition has a kinematic viscosity at minus 40° C. according to ASTM D445 of not more than 600 mm²/s.

9. The ready-to-use heat transfer fluid of claim 1, wherein said fluid has a specific heat capacity at 50° C. of at least 2.0 kJ/kg*K.

10. The ready-to-use heat transfer fluid of claim 9 having increased specific heat capacity due to addition of alkylene glycol ethers according to formula (II).

11. A system comprising at least one heat-generating device using the ready-to-use heat transfer fluid of claim 1, wherein said fluid is circulated in a thermal management system.

12. The system of claim 11, wherein the heat-generating device is selected from fuel cells, battery electric systems, electric motors, power control semiconductors, circuit boards, multi-chip modules, semiconductor devices, semiconductor integrated circuits, servers, and datacenters.
